(19) United States
(12) Patent Application Publication
(10) Pub. No.: US 2024/0155855 A1
(43) Pub. Date: May 9, 2024

(54) SOLAR MODULES WITH INTEGRATED FLEXIBLE HYBRID ELECTRONICS

(71) Applicant: NANOFLEX POWER CORPORATION, Scottsdale, AR (US)

(72) Inventors: Richard FIELD,III, Scottsdale, AR (US); Steven WOLGAST, Scottsdale, AR (US); Olga GRIFFITH, Scottsdale, AR (US); Adam BARITO, Scottsdale, AR (US); J. Norman ALLEN, Scottsdale, AR (US)

(21) Appl. No.: 17/769,665

(22) PCT Filed: Oct. 19, 2020
(86) PCT No.: PCT/US2020/056341

§ 371 Date: Apr. 15, 2022

Related U.S. Application Data
(60) Provisional application No. 62/916,532, filed on Oct. 17, 2019.

(51) Int. Cl. H10K 39/18; H04W 4/80; H10K 30/88; H10K 71/13; H10K 77/10

(52) U.S. Cl. CPC H10K 39/18; H04W 4/80; H10K 30/88; H10K 71/135; H10K 77/111

(57) ABSTRACT

A sensing and/or beacon device comprising: a flexible substrate; a flexible organic photovoltaic (OPV) module comprising a plurality of organic photovoltaic cells disposed on the flexible substrate; a top electrode and a bottom electrode incorporated into the flexible OPV module, wherein the top electrode and the bottom electrode are at least partially exposed; a first encapsulation covering the flexible substrate and the flexible OPV modules, a flexible hybrid electronics (FHE) device disposed on a side of the first encapsulation, wherein the FHE device comprises flexible electronics and die components, the flexible electronics comprising conductive traces, and wherein the FHE device completes an electrical contact with the fop electrode and the bottom electrode; a second encapsulation covering the flexible substrate, the flexible OPV module, the first encapsulation, and the FHE device; and an adhesive disposed on the second encapsulation.

### CROSS-REFERENCE TO RELATED APPLICATION

This application claims the benefit of U.S. Provisional Application No. 62/916,532, filed Oct. 17, 2019, which is incorporated herein by reference in its entirety.

The present disclosure generally relates to photovoltaic modules with integrated flexible hybrid electronic devices.

The present disclosure is directed to a device integrating a photovoltaic module with electronics devices by exposing and utilizing a shared electrical contact. Photovoltaic cells have myriad uses and may be employed to power most devices. Photovoltaic cells may, however, be limited by size, particularly when they are disposed on large, anchored solar panels. Photovoltaic cells may also be limited by power consumption, and/or rigidity.

In order to overcome these limitations, a device in which the photovoltaic module and the electronics device are laminated and/or encapsulated together is provided herein. This solution would expand the uses for photovoltaic module powering since the electronics device would be able to be powered solely by the photovoltaic module and there would be no need for an external source. The onboard photovoltaic module may also increase the available energy and/or extend the lifetime of the device over other solutions including those using batteries and/or capacitors. This would promote a variety of potential improvements including, for example, more frequent or constant communication, the ability to power a greater number of electronics devices, and/or the ability to power higher power-consuming electronics. Moreover. in certain embodiments, the combination of the photovoltaic module and the flexible hybrid electronics device opens the possibility of a dramatic manufacturing cost reduction with roll-to-roll manufacturing of both the flexible photovoltaic module together with the flexible hybrid electronics device.

The devices disclosed herein could be used in downstream markets including, but not limited to, agriculture, indoor farming, ecology, livestock tracking, home automation, Internet of Things (IoT), recreation, wearable devices, smartphones, tablets, computers, watches, jewelry, energy infrastructure, medical monitoring devices and biomedical patches, retail, cold chain, food transport/packaging/storage/preparation/serving, logistics, air/land/water transportation, aerospace, shipping, asset tracking, location/movement/vibration monitoring, architecture, military, defense and surveillance, radar and remote sensing, modular power harvesting and/or radio device, building/home monitoring, tamper resistant monitoring, alert systems, automation, automotive, and building integrated photovoltaics. For example, the proposed device could be used as a flexible smart label, for example, shipping labels and product labels in stores, which are powered completely by the integrated photovoltaic module and which may be attached to all surfaces, including curved or irregular surfaces.

In order to integrate the photovoltaic modules directly with electronics devices, disclosed here are techniques to expose and use a shared electrical contact between the two devices. The photovoltaic module has top and bottom contacts that are exposed by removing the substrate and/or encapsulation material, and then electronics are printed and/or attached to the opposite side from the photovoltaic. The entire device (photovoltaic module plus electronics device) is laminated/encapsulated together, producing a thin, potentially completely self-contained device.

In some embodiments, the entire device is flexible by attaching a flexible electronics device onto a flexible photovoltaic module. For example, the device could be a solar-powered sensor, or a label. The devices can sense and transmit data wirelessly with an onboard radio. The onboard solar can increase the available energy and/or extend the lifetime of the device over other solutions, such as but not limited to using only batteries and/or capacitors. This, for example, promotes more frequent or constant communication, and/or ability to power more electronics that use more energy.

In certain embodiments, the present disclosure is directed to a sensing and/or beacon device comprising: a flexible substrate; a flexible organic photovoltaic (OPV) module comprising a plurality of organic photovoltaic cells disposed on the flexible substrate; a top electrode and a bottom electrode incorporated into the flexible OPV module, wherein the top electrode and the bottom electrode are at least partially exposed; a first encapsulation covering the flexible substrate and the flexible OPV modules, wherein a portion of the first encapsulation may be removed to ensure the top electrode and the bottom electrode remain at least partially exposed; a flexible hybrid electronics (FHE) device disposed on a side of the first encapsulation, wherein the FHE device comprises flexible electronics and die components, the flexible electronics comprising conductive traces, and wherein the FHE device completes an electrical contact with the top electrode and the bottom electrode; a second encapsulation covering the flexible substrate, the flexible OPV module, the first encapsulation, and the FHE device; and an adhesive disposed on the second encapsulation.

There is also presented herein a method for manufacturing a sensing and/or beacon device in the form of an attachable label, comprising: manufacturing a flexible organic photovoltaic (OPV) module comprising a plurality of OPV cells by depositing organic films via one or more of solution processing and vacuum deposition; depositing a top electrode and a bottom electrode onto the flexible OPV module by one or more of vacuum deposition, printing, screen printing, soldering, or painting, the top electrode and the bottom electrode being disposed such that both the top electrode and the bottom electrode may be at least partially exposed; disposing the flexible OPV module on a flexible substrate; applying a first encapsulation covering the flexible OPV module and the flexible substrate; removing a portion of the first encapsulation, the flexible substrate, or both the first encapsulation and the flexible substrate; manufacturing a flexible hybrid electronics (FHE) device comprising flexible electronics and die components, the flexible electronics comprising conductive traces; establishing an electrical contact between the FHE device and the top electrode and the bottom electrode; attaching the FHE device to one or more of the first encapsulation and the flexible substrate; applying a second encapsulation covering the flexible OPV module, the flexible substrate, the first encapsulation, and the FHE device; and disposing an adhesive on the second encapsulation.

There is further disclosed a flexible Internet of Things (IoT) sensing and/or beacon device in the form of an attachable label comprising: a flexible substrate; a flexible organic photovoltaic (OPV) module comprising a plurality of organic photovoltaic cells disposed on the flexible substrate; a top electrode and a bottom electrode incorporated into the flexible OPV module, wherein the top electrode and the bottom electrode are at least partially exposed; a first encapsulation covering the flexible substrate and the flexible OPV modules, wherein a portion of the first encapsulation may be removed to ensure the top electrode and the bottom electrode remain at least partially exposed; a flexible hybrid electronics (FHE) device disposed on a side of the first encapsulation, wherein the FHE device comprises flexible electronics and die components, the flexible electronics comprising conductive traces, and wherein the FHE device completes an electrical contact with the top electrode and the bottom electrode; a second encapsulation covering the flexible substrate, the flexible OPV module, the first encapsulation, and the FHE device; and an adhesive disposed on the second encapsulation.

There is also disclosed a method for manufacturing a flexible Internet of Things (IoT) sensing and/or beacon device in the form of an attachable label, comprising: manufacturing a flexible organic photovoltaic (OPV) module comprising a plurality of OPV cells by depositing organic films via one or more of solution processing and vacuum deposition; depositing a top electrode and a bottom electrode onto the flexible OPV module by one or more of vacuum deposition, printing, screen printing, soldering, or painting, the top electrode and the bottom electrode being disposed such that both the top electrode and the bottom electrode may be at least partially exposed; disposing the flexible OPV module on a flexible substrate; applying a first encapsulation covering the flexible OPV module and the flexible substrate; removing a portion of the first encapsulation, the flexible substrate, or both the first encapsulation and the flexible substrate; manufacturing a flexible hybrid electronics (FHE) device comprising flexible electronics and die components, the flexible electronics comprising conductive traces; establishing an electrical contact between the FHE device and the top electrode and the bottom electrode; attaching the FHE device to one or more of the first encapsulation and the flexible substrate; applying a second encapsulation covering the flexible OPV module, the flexible substrate, the first encapsulation, and the FHE device; and disposing an adhesive on the second encapsulation.

In addition, disclosed here in is a flexible Internet of Things (IoT) radio device in the form of an attachable label comprising: a flexible substrate; a flexible organic photovoltaic (OPV) module comprising a plurality of organic photovoltaic cells disposed on the flexible substrate; a top electrode and a bottom electrode incorporated into the flexible OPV module, wherein the top electrode and the bottom electrode are at least partially exposed; a first encapsulation covering the flexible substrate and the flexible OPV modules, wherein a portion of the first encapsulation may be removed to ensure the top electrode and the bottom electrode remain at least partially exposed; a flexible hybrid electronics (FHE) device disposed on a side of the first encapsulation, wherein the FHE device comprises flexible electronics and die components, the flexible electronics comprising conductive traces, the die components comprising a radio, and wherein the FHE device completes an electrical contact with the top electrode and the bottom electrode; a second encapsulation covering the flexible substrate, the flexible OPV module, the first encapsulation, and the FHE device; and an adhesive disposed on the second encapsulation.

Further disclosed in a method for manufacturing a flexible Internet of things (IoT) radio device in the form of an attachable label, comprising: manufacturing a flexible organic photovoltaic (OPV) module comprising a plurality of OPV cells by depositing organic films via one or more of solution processing and vacuum deposition; depositing a top electrode and a bottom electrode onto the flexible OPV module by one or more of vacuum deposition, printing, screen printing, soldering, or painting, the top electrode and the bottom electrode being disposed such that both the top electrode and the bottom electrode are at least partially exposed; disposing the flexible OPV module on a flexible substrate; applying a first encapsulation covering the flexible OPV module and the flexible substrate; removing a portion of the first encapsulation, the flexible substrate, or both the first encapsulation and the flexible substrate; manufacturing a flexible hybrid electronics (FHE) device comprising flexible electronics and die components, the flexible electronics comprising conductive traces, and the die components comprising a radio; establishing an electrical contact between the FHE device and the top electrode and the bottom electrode; attaching the FHE device to one or more of the first encapsulation and the flexible substrate; applying a second encapsulation covering the flexible OPV module, the flexible substrate, the first encapsulation, and the FHE device; and disposing an adhesive on the second encapsulation.

Other embodiments of the present disclosure are set forth below.

It is to be understood that both the foregoing general description and the following detailed description are exemplary and explanatory only and are not restrictive of the invention, as claimed.

### BRIEF DESCRIPTION OF THE DRAWINGS

The accompanying figures, which are incorporated in and constitute a part of this specification, illustrate several embodiments of the invention and together with the description, serve to explain the principles of the invention.

FIG. 1 is a schematic illustration of a photovoltaic module integrated directly with electronics.

FIGS. 2A-2D are cross-sectional views of a photovoltaic module illuminated from the topside illustrating the process of disposing an electronics device onto a substrate.

FIGS. 3A-3D are cross-sectional views of a photovoltaic module illuminated from the backside illustrating the process of disposing an electronics device onto a substrate.

The drawings described herein are for illustrative purposes only of selected embodiments and not all possible implementations and are not intended to limit the scope of the present disclosure. Corresponding reference numerals indicate corresponding parts throughout the several views of the drawings.

### DETAILED DESCRIPTION

Certain embodiments of the present disclosure are directed to a device comprising a sensor in the form of an attachable label comprising: a flexible substrate; a flexible organic photovoltaic (OPV) module comprising a plurality of organic photovoltaic cells disposed on the flexible substrate; a top electrode and a bottom electrode incorporated into the flexible OPV module, wherein the top electrode and the bottom electrode are at least partially exposed; a first encapsulation covering the flexible substrate and the flexible OPV modules, wherein a portion of the first encapsulation may be removed to ensure the top electrode and the bottom electrode remain at least partially exposed; a flexible hybrid electronics (FHE) device disposed on a side of the first encapsulation, wherein the FHE device comprises flexible electronics and die components, the flexible electronics comprising conductive traces, and wherein the FHE device completes an electrical contact with the top electrode and the bottom electrode; a second encapsulation covering the flexible substrate, the flexible OPV module, the first encapsulation, and the FHE device; and an adhesive disposed on the second encapsulation.

The labels disclosed herein can be used in a variety of applications. A list of non-limited examples is set forth in more detail below:
Agriculture, in which sensors can be used to monitor and automate growing conditions such as, for example, temperature, humidity, CO₂, Lux, PAR (photosynthetic photon flux), soil moisture, soil pH, water pH, VPD (vapor pressure deficit), oxygen, and/or stem diameters;
Indoor farming, in which sensors can be used to monitor and automate growing conditions such as, for example, temperature, humidity, CO₂, Lux, PAR, soil moisture, soil pH, water pH, VPD, oxygen, etc.), and/or stem diameters;
Ecology, in which sensors air temperature can be used to monitor soil moisture, and other climatological parameters such as, for example, O₂, CO₂, methane, etc., in order to generate integrated measurements of ecological phenomena, VPD, and/or TVOC (total volatile organic compounds);
Livestock tracking, in which a location tracking sensor and/or beacon such as, for example location (e.g., GPS) and/proximity (e.g., BLE trilateration, LoRa trilateration, ISM band trilateration), can be placed on livestock to track motion, including whether the livestock is sick and not moving and/or if the livestock moves off the property;
Home automation and Internet of things, in which sensors can be used to monitor temperature, light (intensity and/or color), motion, humidity, position (e.g. window open/closed), CO, fire, leak, moisture, and other sensors to trigger automation such as, for example, turning on or off lights, air conditioning, fans, heating, alarms, cameras, mobile alerts, etc.;
Recreation, in which sensors can be used to measure speed, rotation/swing speed, location, impact, pressure, acceleration, and/or concussion monitoring;
Wearable devices, in which sensors can be used to monitor temperature, pulse, altitude, biomechanical forces, injury detection, linear/rotational acceleration, impact forces, and inertial sensors;
Smartphones/tablets/computers/watches, in which sensors can be used to monitor temperature and/or humidity;
Jewelry, in which sensors and/or beacons can be used to monitor temperature, light, humidity, sound, motion, vibrations, location (e.g., GPS) and/proximity (e.g., BLE trilateration, LoRa trilateration, ISM band trilateration);
Energy infrastructure, in which sensors and/or beacons can be used to monitor methane and other gas sensors location (e.g., GPS) and/proximity (e.g., BLE trilateration, LoRa trilateration, ISM band trilateration) and lake remedial action including, for example, leak detection with automation that turns fans on, closes pipes, sends alerts, etc.;
Medical/Medical monitoring devices and biomedical patches, in which sensors can be used to monitor heart rate, blood glucose, blood oxygen, insulin, body temperature, medical chemical detection, blood pressure, sleep monitoring, respiration rate, lactic acid, hydration, cholesterol, electrocardiogram, electroencephalogram, electromyogram, hemoglobin, and/or anemia;
Retail, in which sensors can be used to monitor temperature, humidity, location, light, proximity, and/or location of products being sold, and/or transmit data containing product specifications;
Cold chain, in which sensors and/or beacons can be used to monitor the cold transport of food, medical supplies/vaccines, etc., by measuring temperature, humidity, light, proximity, location (e.g., GPS) and/proximity (e.g., BLE trilateration, LoRa trilateration, ISM band trilateration);
Food transport/packaging/storage/preparation/serving, in which sensors and/or beacons can be used to monitor temperature, humidity, light, proximity, location (e.g., GPS) and/proximity (e.g., BLE trilateration, LoRa trilateration, ISM band trilateration);
Air/land/water transportation, in which sensors can be used to monitor temperature and/or leaks;
Remote field sensing, in which sensors can be used in the field to monitor wildlife activity and unauthorized entry;
Modular power harvesting and/or radio device, in which sensors can be used to provide power and communication capabilities;
Building/home monitoring, in which sensors can be used to monitor temperature, humidity, light levels, proximity, etc., integrated with smart home automation;
Tamper resistant monitoring, in which sensors and/or beacons can be used to make sure boxes do not open during shipment by placing a stretch sensor on the box, possibly with a drop and GPS sensor;
Alert systems, in which sensors can be used to trigger an alarm system and or send alerts such as, for example email messages, text messages, SMS (short message service) and automated calls upon certain events occurring;
Automation, in which sensors can trigger automation and alerts, from any of the sensors listed here including, for example, climate control for agriculture, or turning fans on if a methane leak is detected;
Automotive, in which sensors can be used to monitor the internal and external operating conditions of the vehicle;
Building integrate photovoltaics, in which sensors can be used to integrating flex OPV (organic photovoltaic) on a building with integrated electronics, sensors, radios, etc.;
Aerospace, in which sensors can be used to measuring inertia, acceleration, speed/velocity, location and/or pressure;
Shipping/logistics, in which sensors and/or beacons can be used to monitor, drop, acceleration, temperature/humidity (food tracking), stretch (in order to make sure package was not opened during shipping), location (e.g., GPS) and/proximity (e.g., BLE trilateration, LoRa trilateration, ISM band trilateration);
Asset tracking, in which sensors and/or beacons can be used to monitor location (e.g., GPS) and/or proximity (e.g., BLE trilateration, LoRa trilateration, ISM band trilateration) and/or measure temperature, humidity, and/or acceleration;
Location/movement/vibration monitoring, in which sensors can be used for asset tracking and to measure for drop events (for example, shipping electronics and fragile items);
Architecture, in which sensors can be used to monitor conditions, such as light, temperature and/or humidity and control automation, such as motion-activated lighting; and
Military/Defense and surveillance, in which sensors can be used to monitor asset tracking, temperature/humidity/location/vibration/acceleration, laser activity and weather.

In certain embodiments, the flexible OPV module contained in the label is one or more of semi-transparent, highly reflective, or opaque.

The OPV module can be made from any combination of series and/or parallel OPV cells, which are arranged to produce the required voltage and current combinations for the electronics device.

In certain embodiments, the flexible OPV module contained in the label comprises organic photovoltaic cells which comprise one of more junctions disposed sequentially.

In certain embodiments, the flexible OPV module contained in the label comprises photo-active materials, the photo-active materials comprising polymers, organic molecules (including pure carbon compounds), or both polymers and organic molecules.

In certain embodiments, the flexible OPV module contained in the label is optimizable for levels of light, the levels of light ranging from 1 lux to 150,000 lux, by one or more of modifying the color of the cell, modifying the transparency of the cell, adding anti-reflective coatings, adding distributed Bragg reflectors, adding micro-patterning, adding a light-trapping structure, modifying the bandgap, adding junctions, and adding elements. In certain embodiments, the optimizable levels of light can range from 1 lux to 100 lux, from 100 lux to 1,000 lux, from 1,000 lux to 10,000 lux, from 500 lux to 2,000 lux from 1,000 lux to 50,000 lux, from 10,000 lux to 50,000 lux, from 50,000 lux to 140,000 lux, and from 100,000 lux to 130,000 lux.

In certain embodiments, the flexible OPV module contained in the label comprises one or more of anti-reflection coatings, ultra-violet protection layers, superlattices, Bragg reflector, infrared reflective layers, ceramics layers, oxide layers, metal oxide layers, micropatterned layers, quantum dots, growth buffers, cap layers, and metamorphic layers.

In certain embodiments, the flexible substrate contained in the label comprises one or more materials chosen from polymers, thermoplastics, composite films, multilayered films, willow glass, acrylic, metal foils, metal alloy foils, paper, fabrics, and textiles.

The FHE devices according to the present disclosure comprise flexible printed electronics and die components. In certain embodiments, the FHE devices further comprise other small components that do not detract from the overall flexibility of the label. For example, the FHE devices may further comprise small resistors commonly used today, such as those used in automotive applications, but which are not considered die components.

The flexible printed electronics according to the present disclosure comprise conductive traces. These conductive traces can also be included in non-limiting and conventional manners. In certain embodiments, the conductive traces can be printed, screen-printed and/or deposited, or the conductive traces can be solder connections.

In certain embodiments, the FHE device contained in the label wraps around the first encapsulation such that the electronics device completes a first electrical contact with the top electrode on a first side of the first encapsulation and a second electrical contact with the bottom electrode on a second side of the first encapsulation, the second side being opposite to the first side.

In certain embodiments, the FHE device contained in the label comprises one or more sensors chosen from sensors for humidity, CO₂, light level, vapor pressure deficit, heat index, water, pH, soil moisture, volumetric soil moisture content, soil pH, accelerometer, temperature, pressure, gas sensing, global positioning system (GPS), ultra-wide band (UWB), trilateration, parametric sensing, CO, oxygen, total volatile organic compounds, chemical, contaminants, conductivity, resistivity, current sensing, current measuring, electrical activity, metal detecting, evapotranspiration, water usage, salinity, pest control, climate monitoring, stem diameters, radiation, rain, snow, wind, lightning, soil nutrients, occupancy, position, status, smoke, fluid leaks, power failure, total dissolved solids, flood, motion, door motion, window motion, photogate, touch, Haptic, displacement level, acoustic frequency, sound frequency, vibration frequency, air flow, Hall effect, fuel level, fluid level, radar, torque, speed, tire pressure, chemicals, infrared, ozone, magnetic, radio direction finder, air pollution, moisture detection, seismometer, airspeed, depth, altimeter, freefall, position, angular rate, shock, tilt, velocity, inertial, force, stress, strain, weight, flame, proximity, presence, stretch, heartbeat, heart rate, blood glucose, blood oxygen, insulin, body temperature, medical chemical detection, blood pressure, sleep monitoring, respiration rate, lactic acid, hydration, cholesterol, electrocardiogram, electroencephalogram, electromyogram, hemoglobin, and anemia.

In certain embodiments, the FHE device contained in the label comprises one or more radios chosen from Bluetooth, Bluetooth Low Energy (BLE), long-term evolution (LTE) or cellular, 4G and 5G cellular, wireless fidelity (Wi-Fi) or IEEE 802.11, long range (LoRa), ultra-wideband (UWB), infrared (IR), radio frequency identification (RFID), active radio frequency identification (ARFID), or other industrial, scientific, and medical band (ISM-band) radios.

In certain embodiments, the FHE device contained in the label comprises one or more of batteries, supercapacitors, thermoelectric devices, light-emitting devices, LEDs, power management chips, logic circuits, microprocessors, microcontrollers, integrated circuits, resistors, capacitors, transistors, inductors, diodes, semiconductors, optoelectronic devices, memristors, micro-electromechanical systems (MEMS) devices, varistors, antennas, transducers, crystals, resonators, terminals, optical detectors, optical emitters, heaters, circuit breakers, fuses, relays, spark gaps, heat sinks, motors, displays, liquid crystal displays (LCD), light-emitting diode displays (LED), microLED, electroluminescent displays (ELD), electrophoretic displays, active matrix organic light-emitting diode displays (AMOLED), organic light-emitting diode displays (OLED), quantum dot displays (QD), quantum light-emitting diode displays (QLED), vacuum florescent displays (VFD), digital light processing displays (DLP), interferometric modulator displays (IMOD), digital microshutter displays (DMS), plasma displays, neon displays, filament displays, surface-conduction electron-emitter displays (SED), field emission displays (FED), Laser TV, carbon nanotube displays, touch screens, external connectors, data storage, piezo devices, speakers, microphones, security chips, and user input controls including buttons, knobs, sliders, switches, joysticks, directional-pads, keypads, and pressure/touch sensors.

In certain embodiments, electrical contact contained in the label is established via one or more of soldering, ultrasonic soldering, conductive epoxy, conductive paste, conductive paints, spot welding, welding, wire bonding, printed conductive inks, mechanical contact, nanowire meshes, graphene, and graphite.

In certain embodiments, electrical contact contained in the label is established via printed conductive inks in contact with bus bars in the flexible OPV module. In further embodiments, the bus bars can comprise a combination of vacuum deposited metals and ultrasonic soldered bus bars.

In certain embodiments, the second encapsulation contained in the label comprises a lamination, the lamination comprising one or more material chosen from plastics, glass, metals, silicones, and elastomers, wherein the one of more material is applied by one or more of thermal lamination, pressure lamination, vacuum lamination, ultra-violet curing, flame lamination, hot melt lamination, extrusion lamination, dry-bond lamination, wet-bond lamination, and solventless lamination. In further embodiments, the second encapsulation comprises a potting coating, the potting coating comprising urethane, parylene, polymers, resins, epoxies, acrylic, paints, tapes, fluorocarbon, nano coatings, hybrid coatings, water-based coatings, and ultra-violet coatings.

In additional embodiments, the second encapsulation contained in the label is applied by one or more of spraying, brushing, vacuum coating, vacuum sealing, vacuum depositing, blade coating, screen printing, dipping, syringe dispensing, pipette dispensing, dropper dispensing, curing, and selective coating . . . .

In additional embodiments, a process for manufacturing the OPV modules in the label comprises one or more of solution processing, vacuum deposition, photo-crosslinking, vacuum thermal evaporation, organic vapor phase deposition, organic vapor jet printing, atomic layer deposition, drop casting, blade coating, inkjet printing, slot-die coating, dip coating, bar coating, and spin coating. In further embodiments, the process for manufacturing the OPV modules comprises one or more of a batch or roll-to-roll manufacturing process wherein the FHE device is attached directly to the OPV module or laminated to the OPV module using heat or adhesives.

In certain embodiments, the labels disclosed herein are used in agriculture, in which sensors can be used to monitor and automate growing conditions such as, for example, temperature, humidity, CO₂, Lux, PAR (photosynthetic photon flux), soil moisture, soil pH, water pH, VPD (vapor pressure deficit), oxygen, and/or stem diameters. In further embodiments, the labels disclosed herein are used in indoor farming, in which sensors can be used to monitor and automate growing conditions such as, for example, temperature, humidity, CO₂, Lux, PAR, soil moisture, soil pH, water pH, VPD, oxygen, etc.), and/or stem diameters.

In other embodiments, the labels disclosed herein are used in livestock tracking, in which a location tracking sensor and/or beacon such as, for example, location (e.g., GPS) and/proximity (e.g., BLE trilateration, LoRa trilateration, ISM band trilateration), can be placed on livestock to track motion. This tracking allows the user to determine whether the livestock is sick and not moving and/or if the livestock moves off the property.

In other embodiments, the labels disclosed herein are used in home automation and Internet of things applications, in which sensors can be used to monitor temperature, light (intensity and/or color), motion, humidity, position (e.g. window open/closed), CO, fire, leak, moisture, and other sensors to trigger and automated task such as, for example, turning on or off lights, air conditioning, fans, heating, alarms, cameras and/or mobile alerts.

In additional embodiments, the labels disclosed herein are used in cold chain management, in which sensors and/or beacons can be used to monitor the cold transport of food, medical supplies/vaccines, etc., by measuring temperature, humidity, light, location (e.g., GPS) and/proximity (e.g., BLE trilateration, LoRa trilateration, ISM band trilateration).

Further embodiments use the labels disclosed in food transport/packaging/storage/preparation/serving, in which sensors and/or beacons can be used to monitor temperature, humidity, light, location (e.g., GPS) and/proximity (e.g., BLE trilateration, LoRa trilateration, ISM band trilateration).

Additional embodiment of the present disclosure use sensors and/or beacons disclosed herein to monitor temperature, humidity, light levels, proximity, etc., integrated with smart home automation. In addition, the present disclosure contemplates the disclosed sensors triggering automation and alerts, from any of the sensors listed here including, for example, climate control for agriculture, or turning fans on if a methane leak is detected.

Further, the disclosed labels can be used in shipping and logistics applications in order to monitor GPS location, drop, acceleration, temperature/humidity (food tracking), proximity (e.g., BLE beacons or trilateration) and/or stretch (in order to make sure package was not opened during shipping.

Moreover, the disclosed labels can be used in asset tracking, in which sensors and/or beacons can be used to monitor location (e.g., GPS) and/proximity (e.g., BLE trilateration, LoRa trilateration, ISM band trilateration).

The OPV modules disclosed herein have many potential advantages over inorganic photovoltaics due to their nontoxic nature, relatively small energy investment for fabrication, conformability to non-planar surfaces, and compatibility with large-area, high-throughput manufacturing processes.

Depending on application specifications, the OPV modules can be manufactured to be semi-transparent, highly reflective, or opaque. Semi-transparent OPV modules can be achieved through using semi-transparent conductive materials (such as indium tin oxide or thin metal) for both top and bottom electrodes. Reflectivity and hue can be controlled via organic material selection and thickness of the organic layers in the OPV module.

In certain embodiments, the OPV modules comprise polymers and/or organic molecules (including pure carbon compounds) as the photo-active materials. Polymer-based and/or organic molecules based OPV modules are solution-processed, requiring carrier solvents and methods such as but not limited to blade-coating, spin-coating, and printing, Some small molecule OPV modules can also be manufactured through vacuum deposition. Further embodiments of the present disclosure are directed to OPV modules manufactured using small molecule materials deposited via vacuum thermal evaporation, organic vapor jet printing, or organic vapor phase deposition. Manufacturing techniques for the OPV modules also include, for example, vacuum deposited, printed, and solution processed

In certain embodiments, the organic films for OPV module applications are deposited by solution processing and/or vacuum deposition. Manufacturing methods include, but are not limited to, vacuum thermal evaporation, organic vapor phase deposition, organic vapor jet printing, atomic layer deposition, drop casting, blade coating, inkjet printing, slot-die coating, dip coating, bar coating, and spin coating. Polymers manufacturing may also include photo-crosslinking methods.

In certain embodiments, the OPV module is flexible with a low stiffness<100 N/m that contain, but not limited to, materials with Young's modulus<150 GPa.

In some embodiments flexible OPV modules may be disposed onto flexible substrate such as but not limited to polymers/thermoplastics (for example, polyimide and polyester films, polyethylene terephthalate, polypropylene, polycarbonate), composite/multilayered films, willow glass, acrylic, metal/metal alloy foils, paper, fabrics/textiles.

The OPV modules may be optimized for any light spectrum, such as sunlight or indoor light, for example, LED (light-emitting diode), fluorescent, incandescent, grow lights, neon lights, mercury vapor, metal halide, high-intensity discharge, bioluminescent, and chemiluminescent, to increase the energy harvesting from solar for a target spectrum. For a given light spectrum, the optimization could target a specific level of light, ranging from 1 lux to 150,000 lux. Non-limiting exemplary ranges of optimized levels of light include, for example; 100 lux to 1,000 lux for indoor applications using artificial light sources; 100 lux to 75,00 lux for growth house applications, such as 5,000 lux to 7,000 lux for seedlings and 15,000 lux to 75,000 lux for vegetative growth; 1,000 lux to 30,000 lux for cloudy outside applications, and 100,000 lux to 140,000 lux for bright sunlight applications.

In certain embodiments, the OPV modules can be optimized for artificial light sources in order to harvest most light in the low-light environments. In such embodiments, there will be enough light to power the device when brought outside even though the OPV module is not optimized for outdoor light.

For example, the OPV modules can be highly tunable to the light spectrum in varying applications. Internally, color and transparency of OPVs can be tuned by increasing or decreasing device layers thicknesses, choosing photoactive materials based on their spectral absorption properties, and varying the ratio of photoactive materials, adding/removing layers and/or junctions. Eternally, the OPV modules can be tuned to a specific light spectrum using anti-reflective coatings, distributed Bragg reflectors, micro-patterning, and other light-trapping structures.

In general, photovoltaic cells are engineered such that their absorption spectrum will accept the emission spectrum of the light source. Tuning can occur by varying the bandgap of an individual junction (or sub-cell), or by adding multiple junctions (or sub-cells) to the devices such that the combined absorption spectrum of the solar cell is matched to the light source—thereby increasing the photovoltaic efficiency. For example, elements can be added to the base solar cell (e.g., adding N to GaAs) to adjust the bandgap.

In some embodiments, the OPV modules can be fabricated in custom shapes to serve functional and/or aesthetic purpose.

The substrate, the OPV modules, and electronics device can be any shape including, but not limited to a polygon, a circle, or any shape made from combinations of straight and curved edges. In certain embodiments, the substrate, the OPV modules, and electronics device can be squares and rectangles for use as a label.

In some embodiments, additional layers may be disposed on the photovoltaic module to enhance its performance, lifetime, manufacturability, aesthetics, and/or add functionality. These layers may be semiconductor, metal, dielectric, and/or insulating layers.

In some embodiments, the additional layers to the photovoltaic module may include, but are not limited to, anti-reflection coatings, UV (ultra-violet) protection layers, superlattices, Bragg reflector, IR (infrared) reflective layer, ceramics layers, oxide layers, metal oxide layers, micropatterned layers, quantum dots, growth buffer and cap layers, and metamorphic layers.

In some embodiments, the electronics device will be a sensor to monitor conditions such as but not limited to humidity, CO₂, light level, vapor pressure deficit, heat index, water pH, soil moisture, volumetric soil moisture content, soil pH, accelerometer, temperature, pressure, gas sensing, GPS, UWB (ultra-wide band) trilateration, parametric sensing, CO, oxygen, total volatile organic compounds, chemical, contaminants, conductivity, resistivity, current sensing/measuring, electrical activity, metal detecting, evapotranspiration, water usage, salinity, pest control, climate monitoring, stem diameters, radiation, rain, snow, wind, lightning, soil nutrients, occupancy, position/status, smoke, fluid leaks, power failure, total dissolved solids, flood, motion, door/window motion, photogate, touch, Haptic, displacement, level, acoustic/sound/vibration/frequency, air flow, Hall effect, fuel level, fluid level, radar, torque, speed, tire pressure, chemicals, infrared, ozone, magnetic, radio direction finder, air pollution, moisture detection, seismometer, airspeed, depth, altimeter, freefall, position, angular rate, shock, tilt, velocity, inertial, force, stress, strain, weight, flame, proximity/presence, stretch, heartbeat, heart rate, blood glucose, blood oxygen, insulin, body temperature, medical chemical detection, blood pressure, sleep monitoring, respiration rate, lactic acid, hydration, cholesterol, electrocardiogram, electroencephalogram, electromyogram, hemoglobin, and anemia.

In certain embodiments of the present disclosure, the overall device may comprise one or more sensors, a radio (such as, for example, Bluetooth, BLE, active RFID, LoRa, or LIE), the required circuitry (for example a power management chip) and firmware.

In other embodiments, the overall device may comprise a radio such as but not limited to Bluetooth, BLE, LTE or cellular, Wi-Fi or IEEE 802.11, LoRa, UWB, IR, RFID (radio frequency identification) or other ISM-band (industrial, scientific, and medical) radios. Different radios are used for different applications. For example, some radios are short range and require lower power, with other radios are longer range and require more power. In certain embodiments directed to indoor applications, low power radios such as Bluetooth and BLE are used where the signal range is not long within a building. In other embodiments directed to outdoor applications, higher-power long-range radios such as LoRa radio for farms, or LTE for moving vehicles are used.

In other embodiments, the electronics devices may attach the following components to the backside of the photovoltaic enabled by the exposed photovoltaic contacts: batteries, supercapacitors, fuel cells, thermoelectric device, light-emitting devices, LEDs, power management chips, logic circuits, microprocessors, microcontroller, integrated circuits, resistors, capacitors, transistors, inductors, diodes, semiconductors, optoelectronic devices, memristor, MEMS (micro-electromechanical systems) device, varistor, antennas, transducers, crystals, resonators, terminals, vacuum tubes, optical detectors/emitters, heaters circuit breaker, fuse, relay, spark gap, heat sink, motor, displays (such as but not limited to LCD (liquid crystal display), LED (light emitting diode), microLED, ELD (electroluminescent display), electrophoretic display, AMOLED (active matrix organic light-emitting diode), OLED (organic light-emitting diode), QD (quantum dot), QLED (quantum light-emitting diode), CRT (cathode ray tube), VFD (vacuum florescent display), DLP (digital light processing), IMOD (interferometric modulator display), DMS (digital microshutter display), plasma, neon, filament), SED (surface-conduction electron-emitter display), FED (field emission display), Laser TV, carbon nanotubes touch screens, external connectors, data storage, piezo devices, speakers, microphones, security chips, and user input controls such as but not limited to buttons, knobs, sliders, switches, joystick, directional-pads, keypad, and pressure/touch sensor.

Lamination may include but is not limited to plastics, glass, metals, silicones, elastomers. Lamination can be achieved, for example but not limited to, thermal/pressure/vacuum lamination, UV curing, vacuum lamination, flame lamination, hot melt lamination, extrusion lamination, dry-bond lamination, wet-bond lamination, and solventless lamination.

Potting/conformal coating may include but is not limited to urethane, parylene, polymers, resins, epoxies, acrylic, paints, tapes, fluorocarbon, nano coatings, hybrid coatings, water-based coating, UV cure coating.

The encapsulation can be applied by, for example but not limited to, spraying, brushing, vacuum coating, vacuum sealing, vacuum depositing, blade coating, screen printing, dipping, syringe/pipette/dropper dispensing, curing, and selective coating.

Additional embodiments of the present disclosure are directed to a device comprising a sensor in the form of an attachable label comprising: a substrate; an organic photovoltaic (OPV) module comprising a plurality of organic photovoltaic cells disposed on the substrate; a top electrode and a bottom electrode incorporated into the flexible OPV module, wherein the top electrode and the bottom electrode are at least partially exposed; a first encapsulation covering the substrate and the OPV modules, wherein a portion of the first encapsulation may be removed to ensure the top electrode and the bottom electrode remain at least partially exposed; a hybrid electronics device disposed on a side of the first encapsulation, wherein the hybrid electronics device comprises electronics and die components, the electronics comprising conductive traces, and wherein the hybrid electronics device completes an electrical contact with the top electrode and the bottom electrode; a second encapsulation covering the substrate, the OPV module, the first encapsulation, and the hybrid electronics device; and an adhesive disposed on the second encapsulation.

In further embodiments, at least one of the substrate, the OPV module, and the hybrid electronics device is rigid. In additional embodiments, at least one of the substrate, the OPV module, and the hybrid electronics device is flexible. In the flexible sensors and labels disclosed herein, it is also contemplated that there may be small rigid components, such as sensors, chips, and die components, that are comprised on the flexible substrate.

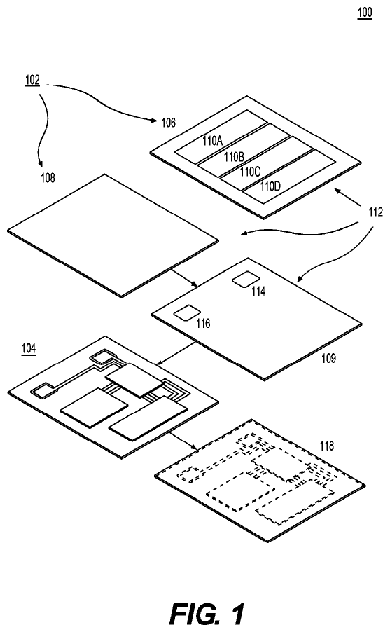

FIG. 1 is a broken out schematic illustration of a photovoltaic module integrated directly with electronics by exposing and using a shared electrical contact between the photovoltaic module and an electronics device. As illustrated in FIG. 1, device 100 may include photovoltaic module 102 and electronics device 104. Photovoltaic module 102 may include an illuminated side 106 corresponding to a side of photovoltaic module 102 which faces light, and an electronics side 108 opposite to illuminated side 106. Illuminated side 106 may include photovoltaic junctions 110a, 110b, 110c, and 110d disposed on a substrate 112. Electronics side 108 may include substrate 112 and optionally an encapsulant (not shown), and may be modified to expose a top contact 114 and a bottom contact 116, producing modified electronics side 109. Electronics device 104 may then be disposed onto the backside of substrate 112 or the encapsulant, aligned with top contact 114 and bottom contact 116 so that there is an electrical connection between electronics device 104 and photovoltaic module 102.

Photovoltaic module 102 may consist of organic photovoltaic (OPV) cells, Ill-Vs (such as but not limited to gallium arsenide (GaAs), gallium indium phosphide (GaInP), gallium aluminum arsenide (GaAlAs)), silicon, cadmium telluride (CdTe), copper indium gallium selenide (CIGS), quantum dots (00), copper zinc tin sulfide (CZTS), and/or perovskites photovoltaic cells. Organic photovoltaic cells have many potential advantages over inorganic photovoltaic cells due to their nontoxic nature, relatively small energy investment for fabrication, conformability to non-planar surfaces, and compatibility with large-area, high-throughput manufacturing processes. In some embodiments, OPV modules may be manufactured to be semi-transparent, highly reflective, or opaque. Semi-transparent OPV modules may be achieved through using semi-transparent conductive materials, such as indium tin oxide or thin metal, for both top and bottom electrodes. Reflectivity and hue may be controlled via organic material selection and thickness of the organic layers in the OPV module. OPV modules may contain polymers and/or organic molecules (including pure carbon compounds) as photo-active materials. Polymer-based and/or organic-molecule-based OPV modules may be solution-processed, requiring carrier solvents and manufacturing methods such as, but not limited to, blade coating, spin coating, and printing. Some small molecule OPV modules may also be manufactured through vacuum deposition. In some embodiments, OPV module manufacturing may involve small molecule materials deposited via vacuum thermal evaporation, organic vapor jet printing, or organic vapor phase deposition. Other manufacturing methods may include, atomic layer deposition, drop casting, inkjet printing, slot-die coating, dip coating, bar coating, and photo-crosslinking

In some embodiments, device 100 may be made flexible by attaching a flexible electronics device 104 onto a flexible photovoltaic module 102, A flexible device 100 may have a low stiffness (e.g., less than 100 N/m) and may contain materials with Glass Young's modulus (e.g., less than 150 GPa). In some embodiments, a flexible photovoltaic module 102 may be disposed onto a flexible substrate 112, wherein the flexible substrate 112 may be made of polymers/thermoplastics (e.g., polyimide and polyester films, polyethylene terephthalate, polypropylene, polycarbonate), composite/multilayered films, willow glass, acrylic, metal/metal alloy foils, paper, fabrics/textiles, and/or other flexible materials.

In some embodiments, photovoltaic module 102 may be optimized for any light spectrum, such as sunlight or artificial light (e.g., LED, fluorescent, incandescent, grow lights, neon lights, mercury vapor, metal halide, high-intensity discharge, bioluminescent, chemiluminescent), to increase the energy harvesting from solar fora target spectrum. For example, for a given light spectrum, the optimization could target a specific level of light, ranging from 1 lux to 150,000 lux. In some embodiments, photovoltaic module 102 may be optimized for indoor light, ensuring that whether device 100 is indoors or outdoors, there will be enough light to power device 100 even though photovoltaic module 102 is not optimized for outdoor light.

In some embodiments, optimizing photovoltaic module 102 may involve changing layers structure, changing layers thickness, and/or adding layers. For example, OPV modules may be highly tunable to the light spectrum in varying applications. Internally, color and transparency of OPV modules may be tuned by increasing or decreasing device layer thicknesses, choosing photoactive materials based on their spectral absorption properties, varying the ratio of photoactive materials, and adding or removing layers. Externally, OPV modules may be tuned to a specific light spectrum using anti-reflective coatings, distributed Bragg reflectors, micro-patterning, and other light-trapping structures. In some embodiments, photovoltaic module 102 may be engineered such that its absorption spectrum may accept the emission spectrum of the light source. This may be tuned by varying the bandgap of an individual sub-cell (e.g., one of junctions 110a-d), or by adding multiple junctions to device 100 such that the combined absorption spectrum of photovoltaic module 102 is matched to the light source—thereby increasing the efficiency of photovoltaic module 102. For example, in inorganic photovoltaic cells, elements may be added to the base photovoltaic cell (e.g., adding N to GaAs) to adjust the bandgap.

In some embodiments, photovoltaic module 102 may be fabricated in custom shapes to serve functional and/or aesthetic purposes. Substrate 112, OPV modules, and flexible electronics devices may take any shape, e.g., a polygon, circle, or any shape made from combinations of straight and curved edges. In some embodiments, additional layers may be disposed on photovoltaic module 102 to enhance its performance, lifetime, manufacturability, aesthetics, and/or add functionality. These layers may be semiconductor, metal, dielectric, and/or insulating layers. In some embodiments, the additional layers added to photovoltaic module 102 may include, but are not limited to, anti-reflection coatings, ultra-violet protection layers, superlattices, Bragg reflectors, infrared reflective layers, ceramics layers, oxide layers, metal oxide layers, micropatterned layers, quantum dots, growth buffer and cap layers, and metamorphic layers.

In some embodiments, electronics device 104 may be a sensor, including but not limited to, sensors for humidity, CO₂, light, level, vapor pressure deficit, heat index, water, pH, soil moisture, volumetric soil moisture content, soil pH, accelerometer, temperature, pressure, gas sensing, global positioning system (GPS), ultra-wide band (UWB), trilateration, parametric sensing, CO, oxygen, total volatile organic compounds, chemical, contaminants, conductivity, resistivity, current sensing/measuring, electrical activity, metal detecting, evapotranspiration, water usage, salinity, pest control, climate monitoring, stem diameters, radiation, rain, snow, wind, lightning, soil nutrients, occupancy, position/status, smoke, fluid leaks, power failure, total dissolved solids, flood, motion, door/window motion, photogate, touch, Haptic, displacement, level, acoustic/sound/vibration/frequency, air flow, Hall effect, fuel level, fluid level, radar, torque, speed, tire pressure, chemicals, infrared, ozone, magnetic, radio direction finder, air pollution, moisture detection, seismometer, airspeed, depth, altimeter, freefall, position, angular rate, shock, tilt, velocity, inertial, force, stress, strain, weight, flame, proximity/presence, stretch, heartbeat, heart rate, blood glucose, blood oxygen, insulin, body temperature, medical chemical detection, blood pressure, sleep monitoring, respiration rate, lactic acid, hydration, cholesterol, electrocardiogram, electroencephalogram, electromyogram, hemoglobin, and anemia. In some embodiments, electronic device 104 may be tailored to each application by changing which sensors and/or radios are included in the electronics, the circuitry, and the firmware.

In some embodiments, electronics device 104 may include radios such as Bluetooth Low Energy (BLE), long-term evolution (LTE) or cellular, Wi-Fi or IEEE 802.11, long range (LoRa), ultra-wideband (UWB), infrared (IR), radio frequency identification (RFID), or other industrial, scientific, and medical band (ISM-band) radios. Different radios may be used for different applications. For example, some radios which have a shorter range and require lower power may be used indoors (e.g., BLE) where the signal range does not have to be long, while others which have a longer range and require more power may be used outdoors (e.g., LoRa radio for farms, or LTE for moving vehicles).

In some embodiments, electronics device 104 may attach the following components to the backside or topside of photovoltaic module 102 enabled by exposed top contact 114 and bottom contact 116: batteries, supercapacitors, fuel cells, thermoelectric devices, light-emitting devices, LEDs, power management chips, logic circuits, microprocessors, microcontrollers, integrated circuits, resistors, capacitors, transistors, inductors, diodes, semiconductors, optoelectronic devices, memristors, micro-electromechanical systems (MEMS) devices, varistors, antennas, transducers, crystals, resonators, terminals, vacuum tubes, optical detectors/emitters, heaters, circuit breakers, fuses, relays, spark gaps, heat sinks, motors, displays (such as, but not limited to, liquid crystal displays (LCD), light-emitting diode (LED), microLED, electroluminescent displays (ELD), electrophoretic displays, active matrix organic light-emitting diode (AMOLED), organic light-emitting diode (OLED), quantum dot (QD), quantum light-emitting diode (OLED), cathode ray tube (CRT), vacuum florescent displays (VFD), digital light processing (DLP), interferometric modulator displays (IMOD), digital microshutter displays (DMS), plasma, neon, filament, surface-conduction electron-emitter displays (SED), field emission displays (FED), Laser TV, and carbon nanotubes), touch screens, external connectors, data storage, piezo devices, speakers, microphones, security chips, and user input controls such as, but not limited to buttons, knobs, sliders, switches, joysticks, directional-pads, keypads, and pressure/touch sensors.

In some embodiments, the electronics components may be flexible, or they may be rigid components such as die electronics components or larger chips, consistent with disclosed embodiments. Rigid components may be placed on a flexible substrate 112, maintaining the overall flexibility of device 100.

Exposed top contact 114 and bottom contact 116 may be electrically connected to electronics device 104 by any means, including but not limited to soldering, ultrasonic soldering, conductive epoxy, conductive paste, conductive paints, spot welding, welding, wire bonding, printed conductive inks, mechanical contact, nanowire meshes, graphene, and graphite. Electronics device 104 may be attached to photovoltaic module 102 by a method including, but not limited to, robotic pick-and-place of components, manually attaching components, attaching components via adhesives, and/or attaching a printed electronics or substrate 112 with electronics device 104. Circuits may be assembled by printing, painting, using electrical connections, and/or any method for manufacturing a circuit.

Once electronics device 104 is integrated with photovoltaic module 102, device 100 may be encapsulated by an encapsulation, as shown by encapsulated electronics 118. Encapsulation may include, but is not limited to, lamination and potting/conformal coating. Lamination may include, but is not limited to, plastics, glass, metals, silicones, and elastomers. Lamination may be achieved, for example, through thermal/pressure/vacuum lamination, UV curing, vacuum lamination, flame lamination, hot melt lamination, extrusion lamination, dry-bond lamination, wet-bond lamination, solventless lamination, and/or any method for sealing device 100 with a material. Potting/conformal coating may include, but is not limited to, urethane, parylene, polymers, resins, epoxies, acrylic, paints, tapes, fluorocarbon, nano coatings, hybrid coatings, water-based coating, solvent-based coating, UV cure coating. Encapsulation may also be applied by, for example, spraying, brushing, vacuum coating, vacuum sealing, vacuum depositing, blade coating, screen printing, dipping, syringe/pipette/dropper dispensing, curing, and selective coating.

Device 100, having undergone the manufacturing process, may be self-contained or may enable attachment to other devices through exposed leads and/or external connectors. In some embodiments, an adhesive or adhesive strip may be disposed on the backside or topside of the lamination to enable simple installation of device 100. This may, for example, enable the device to include a label, sensor, and/or other electronics devices 104 which may be flexible and may need to be placed on boxes, shipping packages, and/or other surfaces which would benefit from an easily-applicable, flexible device.

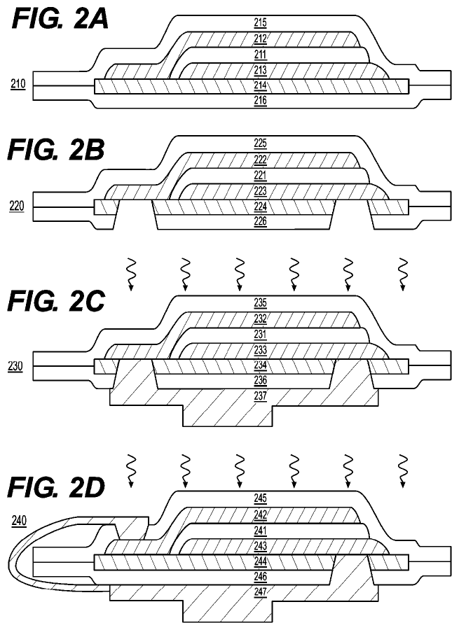

FIGS. 2A-2D are cross-sectional views of a photovoltaic module illuminated from the topside illustrating the process of disposing an electronics device onto a substrate. As illustrated in FIG. 2A, device 210 may include photovoltaic module 211, top contact 212, bottom contact 213, substrate 214, encapsulation 215, and optionally encapsulation 216. Photovoltaic module 211 may be disposed on substrate 214 and may include top contact 212 and bottom contact 213. Top contact 212 and bottom contact 213 may be positive and negative or negative and positive, respectively. Top contact 212 and bottom contact 213 may be arranged such that both may be exposed to be able to complete a connection with the electronics device. Top contact 212 may be deposited beyond bottom contact 213 such that the removal of substrate 214 exposes top contact 212. For topside illumination, top contact 212 and bottom contact 213 may be exposed on the backside of device 210 and may be used to make electrical contact with the flexible electronics for power. Substrate 214 may include a plastic, glass, elastomer, resin, and/or metal. In some embodiments, photovoltaic module 211 and substrate 214 may be encapsulated before integration with electronics via encapsulation 215 and optionally encapsulation 216. Manufacturing methods for device 210 may include, but are not limited to, electron-beam deposition, sputtering, vacuum thermal evaporation, vapor phase deposition, vapor jet printing, atomic layer deposition, drop casting, blade coating, screen printing, inkjet printing, slot-die coating, dip coating, bar coating, spin coating, painting, and/or soldering.

Referring now to FIG. 2B, one or both of top contact 222 and 223 may be made to be accessible from the backside of device 220 and be exposed by removing a portion or all of substrate 224 and any optionally disposed encapsulation 226 under substrate 224. Methods for removing a portion or all of substrate 224 and/or encapsulation 226 may include, but are not limited to, laser ablation, chemical removal, mechanical removal, and/or pre-patterning substrate 224. In some embodiments, device 220 may include active organic, metal, and metal oxide layers and bus bars. When removing a portion or all of substrate 224 and/or encapsulation 226, any material above the bus bar may be ablated, exposing top contact 222 and bottom contact 223. In some embodiments, top contact 222 may be exposed by removing all layers below top contact 222, which may include photovoltaic module 221, bottom contact 223, substrate 224, encapsulation 226, and/or any additional layers. In some embodiments, top contact 222 may extend outside photovoltaic module 221 such that removal of substrate 224 and/or encapsulation 226 may expose top contact 222.

FIG. 2C illustrates an electronics device 237 which may be disposed onto the backside of substrate 234 and/or encapsulation 236 once top contact 232 and bottom contact 233 are exposed to the backside. In some embodiments, circuits, wires, and/or leads may be printed onto substrate 234 and/or encapsulation 236 and die components (e.g., sensors, radios, and/or chips) may be placed afterwards. In some embodiments, electronics device 237 may be flexible, e.g., flexible labels, flexible sensors, and/or flexible tracking devices. Flexible printed electronics for flexible electronics device 237 may be fabricated via an etching process similar to traditional printed electronics or using additive techniques where conductive traces are printed onto a non-conductive substrate 234. The flexible printed electronics may be printed by laying down conductive lines using one of several methods, including, but not limited to, screen, gravure, ink jet, flexography, and other printing methods. To complete flexible electronics device 237, bare die electronic components may be integrated with the flexible circuitry. While some electronic components may be rigid, they may have both low-profiles and/or small footprints which would maintain the overall flexibility of device 230.

As an illustrative example, FIG. 2D shows another method by which electronics device 247 may be disposed onto the backside of substrate 244. In this embodiment, top contact 242 may be exposed on the topside and electronics device 247 may include an electrical connection which wraps around the side of device 240 from the backside to the topside to complete the connection with contact 242.

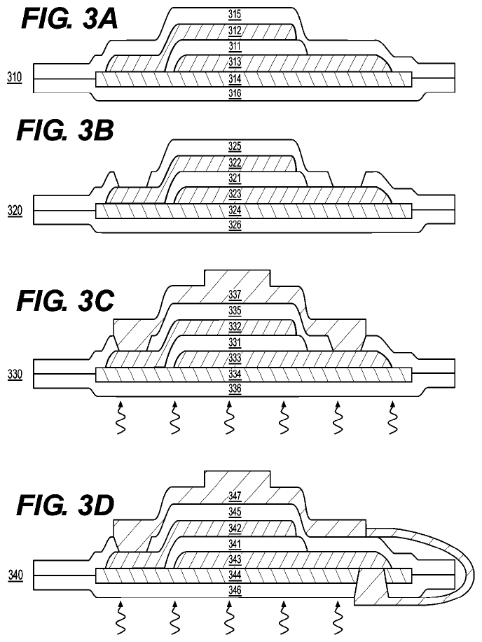

FIGS. 3A-3D are cross-sectional views of a photovoltaic module illuminated from the backside illustrating the process of disposing an electronics device onto a substrate. As illustrated in FIG. 3A, device 310 may include photovoltaic module 311, top contact 312, bottom contact 313, substrate 314, encapsulation 315, and optionally encapsulation 316. Photovoltaic module 311 may be disposed on substrate 314 and may include top contact 312 and bottom contact 313. Top contact 312 and bottom contact 313 may be positive and negative or negative and positive, respectively. Top contact 312 and bottom contact 313 may be arranged such that both may be exposed to be able to complete a connection with the electronics device. Bottom contact 313 may be deposited beyond top contact 312 such that the removal of encapsulation 315 exposes bottom contact 313. For backside illumination, top contact 312 and bottom contact 313 may be exposed on the topside of device 310 and may be used to make electrical contact with the flexible electronics for power. Substrate 314 may include a plastic, glass, elastomer, resin, and/or metal. In some embodiments, photovoltaic module 311 and substrate 314 may be encapsulated before integration with electronics via encapsulation 315 and optionally encapsulation 316. Manufacturing methods for device 310 may include, but are not limited to, electron-beam deposition, sputtering, vacuum thermal evaporation, vapor phase deposition, vapor jet printing, atomic layer deposition, drop casting, blade coating, inkjet printing, slot-die coating, dip coating, bar coating, spin coating, painting, and/or soldering.

Referring now to FIG. 3B, one or both of top contact 322 and 323 may be made to be accessible from the topside of device 320 and be exposed by removing a portion or all of encapsulation 325. Methods for removing a portion or all of encapsulation 325 may include, but are not limited to, laser ablation, chemical removal, mechanical removal, and/or pre-patterning. In some embodiments, device 320 may include active organic and metal oxide layers and bus bars. When removing a portion or all of encapsulation 325, any material above the bus bar may be ablated, exposing top contact 322 and bottom contact 323. In some embodiments, bottom contact 323 may be exposed by removing all layers above bottom contact 323, which may include photovoltaic module 321, top contact 322, encapsulation 325, and/or any additional layers. In some embodiments, bottom contact 323 may extend outside photovoltaic module 321 such that removal of encapsulation 326 may expose bottom contact 323.

FIG. 3C illustrates an electronics device 337 which may be disposed onto the topside of encapsulation 335 once top contact 332 and bottom contact 333 are exposed to the topside. In some embodiments, electronics device 337 may be flexible, e.g., flexible labels, flexible sensors, and/or flexible tracking devices. As an illustrative example, FIG. 3D shows another method by which electronics device 347 may be disposed onto the topside of encapsulation 345. In this embodiment, bottom contact 343 may be exposed on the backside and electronics device 347 may include an electrical connection which wraps around the side of device 340 from the topside to the backside to complete the connection with contact 344.

What is claimed is:

1. A flexible Internet of Things (IoT) sensing and/or beacon device in the form of an attachable label comprising:
a flexible substrate;
a flexible organic photovoltaic (OPV) module comprising a plurality of organic photovoltaic cells disposed on the flexible substrate;
a top electrode and a bottom electrode incorporated into the flexible OPV module, wherein the top electrode and the bottom electrode are at least partially exposed;
a first encapsulation covering the flexible substrate and the flexible OPV modules, wherein a portion of the first encapsulation may be removed to ensure the top electrode and the bottom electrode remain at least partially exposed;
a flexible hybrid electronics (FHE) device disposed on a side of the first encapsulation, wherein the FHE device comprises flexible electronics and die components, the flexible electronics comprising conductive traces, and wherein the FHE device completes an electrical contact with the top electrode and the bottom electrode;
a second encapsulation covering the flexible substrate, the flexible OPV module, the first encapsulation, and the FHE device; and
an adhesive disposed on the second encapsulation.

2. The label of claim 1, wherein the flexible OPV module comprises photovoltaic cells which comprise one or more junctions disposed sequentially.

3. The label of claim 1, wherein the flexible OPV module comprises photo-active materials, the photo-active materials comprising polymers, organic molecules, or both polymers and organic molecules.

4. The label of claim 1, wherein a process for manufacturing the OPV modules comprises one or more of solution processing, vacuum deposition, photo-crosslinking, vacuum thermal evaporation, organic vapor phase deposition, organic vapor jet printing, atomic layer deposition, drop casting, blade coating, inkjet printing, slot-die coating, dip coating, bar coating, and spin coating.

5. The label of claim 1, wherein a process for manufacturing the OPV modules comprises one or more of a batch or roll-to-roll manufacturing process wherein the FHE device is attached directly to the OPV module or laminated to the OPV voltaic module using heat or adhesives.

6. The label of claim 1, wherein the OPV module is optimizable for levels of light, the levels of light ranging from 1 lux to 150,000 lux, by one or more of modifying the color of the cell, modifying the transparency of the cell, adding anti-reflective coatings, adding distributed Bragg reflectors, adding micro-patterning, adding a light-trapping structure, modifying the bandgap, adding junctions, and adding elements.

7. The label of claim 1, wherein the OPV module comprises one or more of anti-reflection coatings, ultra-violet protection layers, superlattices, Bragg reflector, infrared reflective layers, ceramics layers, oxide layers, metal oxide layers, micropatterned layers, quantum dots, growth buffers, cap layers, and metamorphic layers.

8. The label of claim 1, wherein the flexible substrate comprises one or more materials chosen from polymers, thermoplastics, composite films, multilayered films, willow glass, acrylic, metal foils, metal alloy foils, paper, fabrics, and textiles.

9. The label of claim 1, wherein the FHE device wraps around the first encapsulation such that the FHE device completes a first electrical contact with the top electrode on a first side of the first encapsulation and a second electrical contact with the bottom electrode on a second side of the first encapsulation, the second side being opposite to the first side.

10. The label of claim 1, wherein the FHE device comprises one or more sensors chosen from sensors for humidity, CO₂, light level, vapor pressure deficit, heat index, water, pH, soil moisture, volumetric soil moisture content, soil pH, accelerometer, temperature, pressure, gas sensing, global positioning system (GPS), ultra-wide band (UWB), trilateration, parametric sensing, CO, oxygen, total volatile organic compounds, chemical, contaminants, conductivity, resistivity, current sensing, current measuring, electrical activity, metal detecting, evapotranspiration, water usage, salinity, pest control, climate monitoring, stem diameters, radiation, rain, snow, wind, lightning, soil nutrients, occupancy, position, status, smoke, fluid leaks, power failure, total dissolved solids, flood, motion, door motion, window motion, photogate, touch, Haptic, displacement level, acoustic frequency, sound frequency, vibration frequency, air flow, Hall effect, fuel level, fluid level, radar, torque, speed, tire pressure, chemicals, infrared, ozone, magnetic, radio direction finder, air pollution, moisture detection, seismometer, airspeed, depth, altimeter, freefall, position, angular rate, shock, tilt, velocity, inertial, force, stress, strain, weight, flame, proximity, presence, stretch, heartbeat, heart rate, blood glucose, blood oxygen, insulin, body temperature, medical chemical detection, blood pressure, sleep monitoring, respiration rate, lactic acid, hydration, cholesterol, electrocardiogram, electroencephalogram, electromyogram, hemoglobin, and anemia.

11. The label of claim 1, wherein the FHE device comprises one or ore radios chosen from Bluetooth, Bluetooth Low Energy (BLE), long-term evolution (LTE) or cellular, 4G and 5G cellular, wireless fidelity (Wi-Fi) or IEEE 802.11, long range (LoRa), ultra-wideband (UWB), infrared (IR), radio frequency identification (RFID), active radio frequency identification (ARFID), or other industrial, scientific, and medical band (ISM-band) radios.

12. The label of claim 1, wherein the FHE device comprises one or more of batteries, supercapacitors, thermoelectric devices, light-emitting devices, LEDs, power management chips, logic circuits, microprocessors, microcontrollers, integrated circuits, resistors, capacitors, transistors, inductors, diodes, semiconductors, optoelectronic devices, memristors, micro-electromechanical systems (MEMS) devices, varistors, antennas, transducers, crystals, resonators, terminals, optical detectors, optical emitters, heaters, circuit breakers, fuses, relays, spark gaps, heat sinks, motors, displays, liquid crystal displays (LCD), light-emitting diode displays (LED), microLED, electroluminescent displays (ELD), electrophoretic displays, active matrix organic light-emitting diode displays (AMOLED), organic light-emitting diode displays (OLED), quantum dot displays (QD), quantum light-emitting diode displays (QLED), vacuum florescent displays (VFD), digital light processing displays (DLP), interferometric modulator displays (IMOD), digital microshutter displays (DMS), plasma displays, neon displays, filament displays, surface-conduction electron-emitter displays (SED), field emission displays (FED), Laser TV, carbon nanotube displays, touch screens, external connectors, data storage, piezo devices, speakers, microphones, security chips, and user input controls including buttons, knobs, sliders, switches, joysticks, directional-pads, keypads, and pressure/touch sensors.

13. The label of claim 1, wherein the electrical contact is established via one or more of soldering, ultrasonic soldering, conductive epoxy, conductive paste, conductive paints, spot welding, welding, wire bonding, printed conductive inks, mechanical contact, nanowire meshes, graphene, and graphite.

14. The label of claim 1, wherein the electrical contact is established via printed conductive inks in contact with bus bars in the flexible OPV module.

15. The label of claim 1, wherein the second encapsulation comprises a lamination, the lamination comprising one or more material chosen from plastics, glass, metals, silicones, and elastomers, wherein the one of more material is applied by one or more of thermal lamination, pressure lamination, vacuum lamination, ultra-violet curing, flame lamination, hot melt lamination, extrusion lamination, dry-bond lamination, wet-bond lamination, and solventless lamination.

16. The label of claim 1, wherein the second encapsulation comprises a potting coating, the potting coating comprising urethane, parylene, polymers, resins, epoxies, acrylic, paints, tapes, fluorocarbon, nano coatings, hybrid coatings, water-based coatings, solvent-based coating, and ultra-violet coatings.

17. The label of claim 1, wherein the second encapsulation is applied by one or more of spraying, brushing, vacuum coating, vacuum sealing, vacuum depositing, blade coating, screen printing, dipping, syringe dispensing, pipette dispensing, dropper dispensing, curing, and selective coating.

18. A method for manufacturing a flexible Internet of Things (IoT) sensing and/or beacon device in the form of an attachable label, comprising:
manufacturing a flexible organic photovoltaic (OPV) module comprising a plurality of OPV cells by depositing organic films via one or more of solution processing and vacuum deposition;
depositing a top electrode and a bottom electrode onto the flexible OPV module by one or more of vacuum deposition, printing, screen printing, soldering, or painting, the top electrode and the bottom electrode being disposed such that both the top electrode and the bottom electrode are at least partially exposed;
disposing the flexible OPV module on a flexible substrate;
applying a first encapsulation covering the flexible OPV module and the flexible substrate;
removing a portion of the first encapsulation, the flexible substrate, or both the first encapsulation and the flexible substrate;
manufacturing a flexible hybrid electronics (FHE) device comprising flexible electronics and die components, the flexible electronics comprising conductive traces;
establishing an electrical contact between the FHE device and the top electrode and the bottom electrode;
attaching the FHE device to one or more of the first encapsulation and the flexible substrate;
applying a second encapsulation covering the flexible OPV module, the flexible substrate, the first encapsulation, and the FHE device; and
disposing an adhesive on the second encapsulation.

19. The method of claim 18, wherein manufacturing the FHE device comprises:
printing conductive traces on the backside of the flexible OPV module via an etching process utilizing additive techniques; and
integrating the die components onto the backside of the flexible OPV module, wherein the die components may be rigid.

20. The method of claim 18, wherein removing a portion of the first encapsulation, the flexible substrate, or both the first encapsulation and the flexible substrate comprises one or more of laser ablation, chemical removal, mechanical removal, and pre-patterning.

21. The method of claim 18, wherein applying the first encapsulation and the second encapsulation comprises one or more of thermal lamination, pressure lamination, vacuum lamination, ultra-violet curing, flame lamination, hot melt lamination, extrusion lamination, dry-bond lamination, wet-bond lamination, solventless lamination, spraying, brushing, vacuum coating, vacuum sealing, vacuum depositing, blade coating, screen printing, dipping, syringe dispensing, pipette dispensing, dropper dispensing, curing, and selective coating.

22. A flexible Internet of Things (IoT) radio device in the form of an attachable label comprising:
a flexible substrate;
a flexible organic photovoltaic (OPV) module comprising a plurality of organic photovoltaic cells disposed on the flexible substrate;
a top electrode and a bottom electrode incorporated into the flexible OPV module, wherein the top electrode and the bottom electrode are at least partially exposed;
a first encapsulation covering the flexible substrate and the flexible OPV modules, wherein a portion of the first encapsulation may be removed to ensure the top electrode and the bottom electrode remain at least partially exposed;
a flexible hybrid electronics (FHE) device disposed on a side of the first encapsulation, wherein the FHE device comprises flexible electronics and die components, the flexible electronics comprising conductive traces, the die components comprising a radio, and wherein the FHE device completes an electrical contact with the top electrode and the bottom electrode;
a second encapsulation covering the flexible substrate, the flexible OPV module, the first encapsulation, and the FHE device; and
an adhesive disposed on the second encapsulation.

23. The label of claim 22, wherein the FHE device comprises one or more radios chosen from Bluetooth, Bluetooth Low Energy (BLE), long-term evolution (LTE) or cellular, 4G and 5G cellular, wireless fidelity (Wi-Fi) or IEEE 802.11, long range (LoRa), ultra-wideband (UWB), infrared (IR), radio frequency identification (RFID), active radio frequency identification (ARFID), or other industrial, scientific, and medical band (ISM-band) radios.

24. A method for manufacturing a flexible Internet of things (IoT) radio device in the form of an attachable label, comprising:
manufacturing a flexible organic photovoltaic (OPV) module comprising a plurality of OPV cells by depositing organic films via one or more of solution processing and vacuum deposition;
depositing a top electrode and a bottom electrode onto the flexible OPV module by one or more of vacuum deposition, printing, screen printing, soldering, or painting, the top electrode and the bottom electrode being disposed such that both the top electrode and the bottom electrode are at least partially exposed;
disposing the flexible OPV module on a flexible substrate;
applying a first encapsulation covering the flexible OPV module and the flexible substrate;
removing a portion of the first encapsulation, the flexible substrate, or both the first encapsulation and the flexible substrate;
manufacturing a flexible hybrid electronics (FHE) device comprising flexible electronics and die components, the flexible electronics comprising conductive traces, and the die components comprising a radio;
establishing an electrical contact between the FHE device and the top electrode and the bottom electrode;
attaching the FHE device to one or more of the first encapsulation and the flexible substrate;
applying a second encapsulation covering the flexible OPV module, the flexible substrate, the first encapsulation, and the FHE device; and
disposing an adhesive on the second encapsulation.

25. The label of claim 24, wherein the FHE device comprises one or more radios chosen from Bluetooth, Bluetooth Low Energy (BLE), long-term evolution (LTE) or cellular, 4G and 5G cellular, wireless fidelity (Wi-Fi) or IEEE 802.11, long range (LoRa), ultra-wideband (UWB), infrared (IR), radio frequency identification (RFID), active radio frequency identification (ARFID), or other industrial, scientific, and medical band (ISM-band) radios.

26. A flexible Internet of things (IoT) automatic control system in the form of an attachable label comprising:
a flexible substrate;
a flexible organic photovoltaic (OPV) module comprising a plurality of organic photovoltaic cells disposed on the flexible substrate;
a top electrode and a bottom electrode incorporated into the flexible OPV module, wherein the top electrode and the bottom electrode are at least partially exposed;
a first encapsulation covering the flexible substrate and the flexible OPV modules, wherein a portion of the first encapsulation may be removed to ensure the top electrode and the bottom electrode remain at least partially exposed;
a flexible hybrid electronics (FHE) device disposed on a side of the first encapsulation, wherein the FHE device comprises flexible electronics and die components, the flexible electronics comprising conductive traces, the die components comprising a programmable controller, and wherein the FHE device completes an electrical contact with the top electrode and the bottom electrode;
a second encapsulation covering the flexible substrate, the flexible OPV module, the first encapsulation, and the FHE device; and
an adhesive disposed on the second encapsulation.

27. A method for manufacturing a flexible internet of things (IoT) automatic control system in the form of an attachable label, comprising:
manufacturing a flexible organic photovoltaic (OPV) module comprising a plurality of OPV cells by depositing organic films via one or more of solution processing and vacuum deposition;
depositing a top electrode and a bottom electrode onto the flexible OPV module by one or more of vacuum deposition, printing, screen printing, soldering, or painting, the top electrode and the bottom electrode being disposed such that both the top electrode and the bottom electrode are at least partially exposed;
disposing the flexible OPV module on a flexible substrate;
applying a first encapsulation covering the flexible OPV module and the flexible substrate;
removing a portion of the first encapsulation, the flexible substrate, or both the first encapsulation and the flexible substrate;
manufacturing a flexible hybrid electronics (FHE) device comprising flexible electronics and die components, the flexible electronics comprising conductive traces, and the die components comprising a programmable controller;
establishing an electrical contact between the FHE device and the top electrode and the bottom electrode;
attaching the FHE device to one or more of the first encapsulation and the flexible substrate;
applying a second encapsulation covering the flexible OPV module, the flexible substrate, the first encapsulation, and the FHE device; and
disposing an adhesive on the second encapsulation.
